(19) United States
(12) Patent Application Publication
(10) Pub. No.: US 2015/0020593 A1
(43) Pub. Date: Jan. 22, 2015

(54) APPARATUS FOR DRIVING INERTIAL SENSOR AND CONTROLLING METHOD OF THE SAME

(71) Applicant: SAMSUNG ELECTRO-MECHANICS CO., LTD., Suwon-Si (KR)

(72) Inventors: Kyung Rin Kim, Suwon-Si (KR); Byoung Won Hwang, Suwon-Si (KR); Chang Hyun Kim, Suwon-Si (KR)

(73) Assignee: SAMSUNG ELECTRO-MECHANICS CO., LTD., Suwon-Si (KR)

(21) Appl. No.: 14/317,423

(22) Filed: Jun. 27, 2014

(30) Foreign Application Priority Data
Jul. 22, 2013 (KR) 10-2013-0086290

(51) Int. Cl. G01P 15/08; H03B 5/30

(52) U.S. Cl. CPC G01P 15/08; H03B 5/30
USPC 73/514.35

(57) ABSTRACT

Disclosed herein is an apparatus for driving an inertial sensor, the apparatus including: at least one inertial sensor including a driving mass; an analog circuit unit detecting an amplitude value and a phase value of a driving mass resonance from a driving displacement signal of the inertial sensor; a first signal converting unit converting the amplitude value and the phase value into a digital value; a digital automatic gain control unit generating a control gain for controlling an amplitude or phase of the driving mass resonance so that the digitalized amplitude value or the phase value converges on a preset target value; and a second signal converting unit converting the control gain into an analog value and transmitting the analog value to the analog circuit unit, wherein the analog circuit unit applies a driving signal having the control gain reflected thereto to the inertial sensor.

### CROSS REFERENCE TO RELATED APPLICATION

This application claims the benefit of Korean Patent Application No. 10-2013-0086290, filed on Jul. 22, 2013, entitled “Apparatus and Method for Driving Inertial Sensor”, which is hereby incorporated by reference in its entirety into this application.

### BACKGROUND OF THE INVENTION

1. Technical Field

The present invention relates to an apparatus for driving an inertial sensor and a controlling method of the same.

2. Description of the Related Art

Mobile devices, which have been recently developed, having an inertial sensor (an accelerator sensor, an inertial sensor, a geomagnetic sensor, or the like) mounted therein using inertial input applied from the outside have been generally released. Among various inertial sensors described above, the inertial sensor is a sensor capable of measuring a corresponding angular velocity by detecting an amount of applied rotating force of an object. The angular velocity may be obtained by Coriolis' force “F=2mΩ V”, where m represents a mass of a sensor mass, Ω represents an angular velocity to be measured, and V represents a motion velocity of the sensor mass.

FIG. 1 illustrates a principle of detecting the angular velocity of the inertial sensor. When the mass of the sensor resonates in an X direction and the rotating force is applied to a Z direction, the Coriolis' force is generated in a Y direction to convert the corresponding signal into an electrical signal and the converted signal detects inertial force for the angular velocity by a predetermined signal processing procedure from a control circuit of the inertial sensor. Therefore, in order to detect stable inertial input, it is important to always stably perform the resonance of the mass of the inertial sensor.

In addition, in order to stably perform the resonance of the mass of the inertial sensor, a mass resonance amplitude control and a phase control are most important, where the mass resonance amplitude control is performed so that the mass may always resonate at a constant amplitude and the phase control is performed so that a difference between a signal generated from the control circuit to perform the resonance of the mass and a phase at which the mass resonates may be always constantly maintained.

Therefore, in general, because a phase or amplitude control scheme of the mass resonance of the inertial sensor according to the prior art such as in Patent Document described in the following prior art document has manually set a control value or used an analog circuit (e.g., a phase locked loop or a feedback loop), a variation in the mass due to modification of an MEMS structure body may not be corrected by a real-time monitoring and a consumed current, and the like may be increased due to a relative increase in a circuit size in terms of the control scheme using the analog circuit.

### PRIOR ART DOCUMENT

### Patent Document

(Patent Document 1) JP2004212111

### SUMMARY OF THE INVENTION

The present invention has been made in an effort to provide an apparatus for driving an inertial sensor capable of decreasing a size of an entire circuit and a consumed current and performing a control having high degree of precision by a digital automatic gain control unit of a digital scheme and a proportional integral control (PID control) to perform a stable control of a phase and an amplitude of driving mass resonance of the inertial sensor, and a controlling method of the same.

According to a preferred embodiment of the present invention, there is provided an apparatus for driving an inertial sensor, the apparatus including: an inertial sensor including at least one driving mass; an analog circuit unit detecting an amplitude value and a phase value of a driving mass resonance from a driving displacement signal of the inertial sensor; a first signal converting unit converting the amplitude value and the phase value into a digital value; a digital automatic gain control unit selectively executing an operation of a control gain for an amplitude or phase of the driving mass resonance so that any one of the amplitude value or the phase value received from the first signal converting unit first converges on a preset target value; and a second signal converting unit converting the control gain into an analog value and transmitting the analog value to the analog circuit unit.

The digital automatic gain control unit may selectively receive data for a signal of any one of the amplitude value or the phase value from the first signal converting unit depending on a response speed of the driving mass applied with the control gain of the amplitude or phase.

The first signal converting unit may be an analog to digital (A/D) converter.

The second signal converting unit may be a digital to analog (D/A) converter.

The analog circuit unit may include: an analog control module generating a driving signal to which the control gain for the phase or amplitude of the driving mass resonance is reflected, applying the driving signal to the inertial sensor, and receiving a driving displacement signal from the inertial sensor; an amplitude detection module of the driving mass resonance mixing the driving displacement signal with a signal having a phase retarded by 90° compared to the driving signal to thereby detect the amplitude value of the driving mass resonance; a phase detection module of the driving mass resonance mixing the driving displacement signal with the driving signal to thereby detect the phase value of the driving mass resonance; and an analog Mux selectively transmitting the amplitude value or the phase value of the driving mass resonance to the digital automatic gain control unit.

The digital automatic gain control unit may include: a data selection module selectively receiving data for the amplitude value or the phase value of the driving mass resonance depending on a preset rate coefficient by considering a response speed of the driving mass applied with the control gain; a gain control module executing an operation for generating the control gain of the phase of amplitude so that the amplitude or phase of the driving mass resonance reaches a preset target value; and a data processing control module performing a control so that an operation of a control gain for other signals is executed, after any one of the amplitude or phase of the driving mass resonance converges on the preset target value by the gain control module.

The digital automatic gain control unit may include: a memory storing a pre-operated control gain for the amplitude or phase of the driving mass resonance so that the amplitude value or the phase value of the driving mass resonance approaches the target value; and a timer counting an operation execution time of the control gain for the amplitude or phase of the driving mass resonance in the gain control module.

The gain control module may use the control gain stored in the memory at the time of initially driving the driving mass as a control gain for controlling the phase or amplitude of the driving mass resonance.

The timer may determine whether or not the operation execution time exceeds a preset time value, and then transmits a timeout signal to the data processing control module and the gain control module when the operation execution time exceeds the preset time value.

The data processing control module may transmit only data for other signals to the gain control module after receiving the timeout signal, and the gain control module may execute an operation of a gain control for other signals after terminating the operation execution.

The timer may initialize the counted time value when receiving a lock flag signal for the amplitude or phase of the driving mass resonance from the gain control module or transmitting the timeout signal.

The digital automatic gain control unit may further include a filter unit provided between the data selection module and the gain control module and removing a noise included in the amplitude value or the phase value of the driving mass resonance.

The gain control module may transmit a lock flag signal indicating that a value converged on the preset target value is maintained to the data processing control module, when any one of the phase or amplitude of the driving mass resonance converges on the preset target value.

The data processing control module may transmit only data for a signal not converging on the preset target value among the phase or amplitude of the driving mass resonance when receiving the lock flag signal to the gain control module.

According to another preferred embodiment of the present invention, there is provided a controlling method of an apparatus for driving an inertial sensor, the method including: detecting, by an analog circuit unit, an amplitude value and a phase value of a driving mass resonance from a driving displacement signal of an inertial sensor; converting, by a first signal converting unit, the amplitude value or the phase value into a digital value; selectively executing, by a digital automatic gain control unit, an operation of a control gain for an amplitude or phase of the driving mass resonance so that any one of the amplitude value or the phase value received from the first signal converting unit first converges on a preset target value; and converting, by a second signal converting unit, the control gain into an analog value to thereby transmit the analog value to the analog circuit unit.

The selectively executing, by a digital automatic gain control unit, of the operation of the control gain for the amplitude or phase of the driving mass resonance may include: selectively receiving data for a signal of any one of the amplitude value or the phase value from the first signal converting unit depending on a response speed of the driving mass applied with the control gain of the amplitude or phase; and executing an operation of a control gain for other signals after any one of the amplitude value or the phase value converges on a preset target value by the operation of the control gain for the amplitude or phase of the driving mass resonance.

The detecting of the amplitude value and the phase value of the driving mass resonance may include: applying, by an analog control module, a driving signal having the control gain reflected thereto to the inertial sensor and receiving a driving displacement signal from the inertial sensor; mixing, by an amplitude detection unit of the driving mass resonance, the driving displacement signal with a signal having a phase retarded by 90° compared to the driving signal to thereby detect the amplitude value of the driving mass resonance; mixing, by a phase detection unit of the driving mass resonance, the driving displacement signal with the driving signal to thereby detect the phase value of the driving mass resonance; and selectively transmitting, by an analog Mux, the amplitude value or the phase value of the driving mass resonance to the digital automatic gain control unit.

The selectively executing of the operation of the control gain for the amplitude or phase of the driving mass resonance may include: selectively receiving, by a data selection module, data for the amplitude value or the phase value depending on a preset rate coefficient; comparing, by a gain control module, the amplitude value or the phase value with a preset target value and generating a control gain for the phase or amplitude when the comparison result is different; and performing, by a data processing control module, a control so that an operation of a control gain for other signals is executed, after any one of the amplitude or phase of the driving mass resonance converges on the preset target value by the gain control module.

The controlling method may further include, after the generating of the control gain by the gain control module, counting, by a timer, an operation execution time of the control gain for the amplitude or phase of the driving mass resonance by the gain control module and determining whether or not the operation execution time exceeds a preset time value; and transmitting, by the timer, a timeout signal to the data processing control module and the gain control module when the operation execution time exceeds the preset time value.

The controlling method may further include: transmitting, by the data processing control module, only data for other signals to the gain control module after receiving the timeout signal, and executing, by the gain control module, an operation of a gain control for other signals after terminating the operation execution.

The controlling method may further include, after the selectively receiving, by the data selection module, of the data for the amplitude value or the phase value, removing, by a filter unit, a noise included in the amplitude value or the phase value.

The performing, by the data processing control module, of the control so that the operation of the control gain for other signals is executed may include: transmitting, by the gain control module, a lock flag signal when any one of the phase or amplitude of the driving mass resonance converges on the preset target value; and transmitting, by the data processing control module receiving the lock flag signal, only data for a signal not converging on the preset target value among the phase or amplitude to the gain control module.

The first signal converting unit may be an analog to digital (A/D) converter.

The second signal converting unit may be a digital to analog (D/A) converter.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram showing a principle of detecting an angular velocity of an inertial sensor;

FIG. 2 is a block diagram showing a driving apparatus of an inertial sensor according to a preferred embodiment of the present invention;

FIGS. 3A and 3B are diagrams showing first and second signal converting units according to a preferred embodiment of the present invention;

FIG. 4 is a diagram showing an entire system for the driving apparatus of the inertial sensor according to the preferred embodiment of the present invention;

FIG. 5 is a view showing a configuration of an analog circuit unit according to a preferred embodiment of the present invention;

FIGS. 6A and 6B are diagrams for describing processes detecting phase and amplitude values of driving mass resonance from amplitude and phase detection modules of the driving mass resonance according to a preferred embodiment of the present invention;

FIGS. 7A and 7B are diagrams showing configurations of a digital automatic gain control unit according to a preferred embodiment of the present invention;

FIG. 8 is a diagram showing a procedure processing data in a data selection module according to a preferred embodiment of the present invention;

FIG. 9 is a diagram showing a procedure processing data between a data processing control module and a gain control module according to a preferred embodiment of the present invention; and

FIG. 10 is a flowchart showing a control method for the driving apparatus of the inertial sensor according to a preferred embodiment of the present invention.

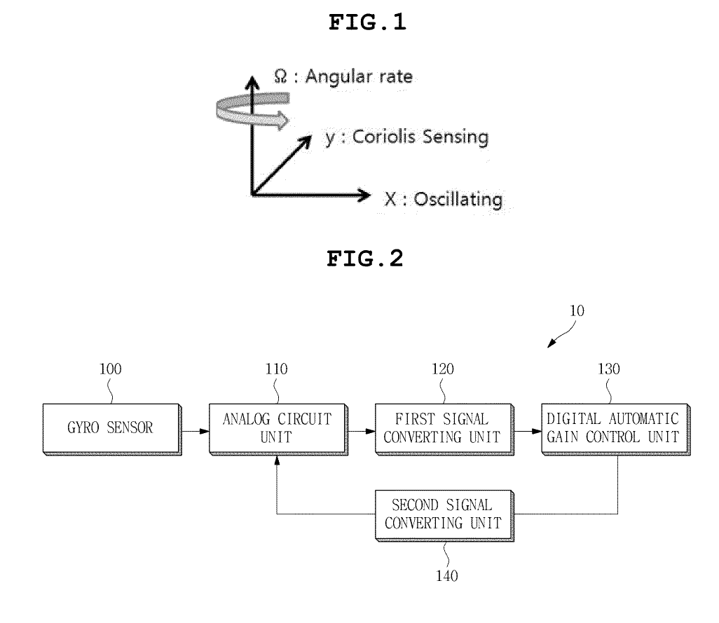

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

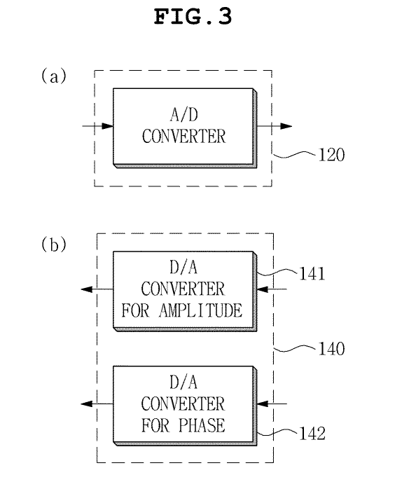

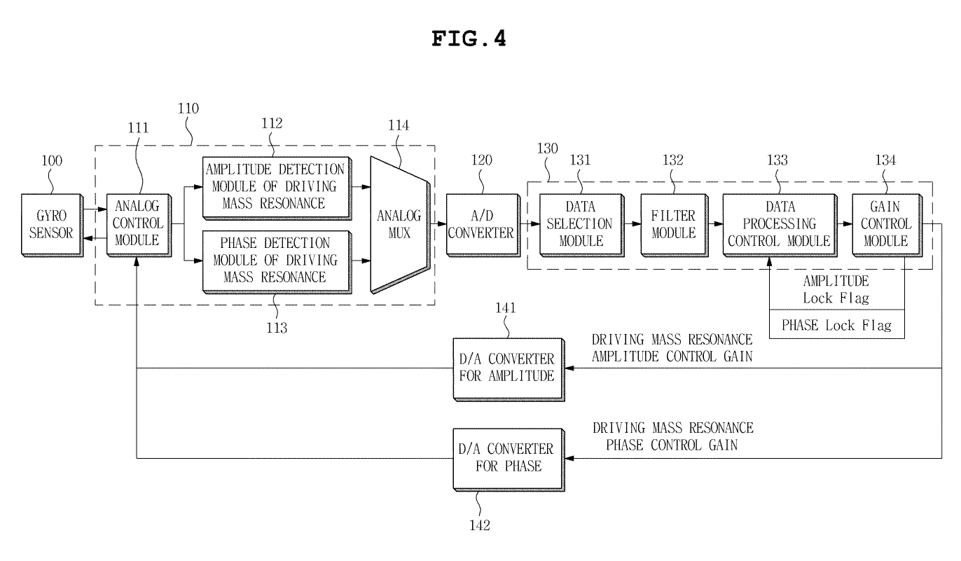

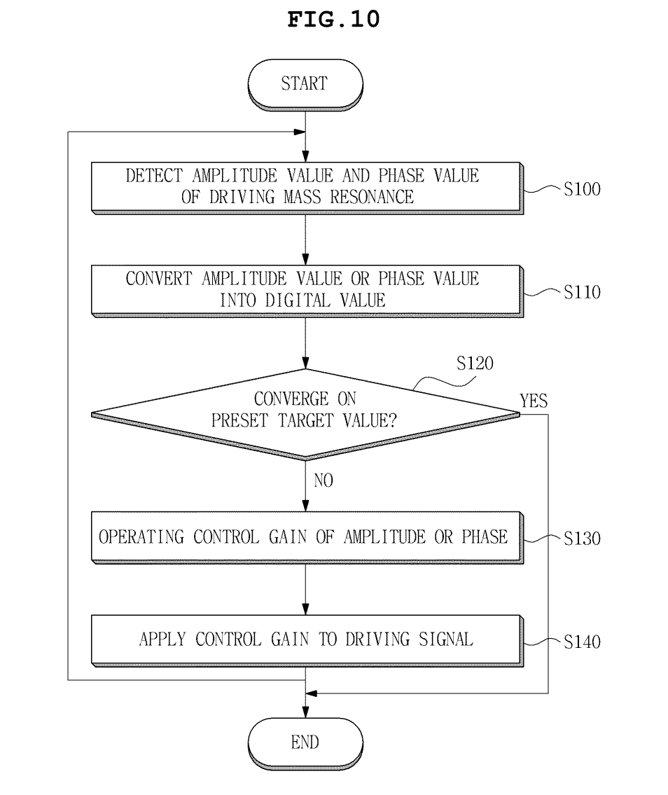

FIG. 2 is a block diagram showing a driving apparatus of an inertial sensor according to a preferred embodiment of the present invention, FIGS. 3A and 3B are diagrams showing first and second signal converting units according to a preferred embodiment of the present invention, FIG. 4 is a diagram showing an entire system for the driving apparatus of the inertial sensor according to the preferred embodiment of the present invention, and FIG. 10 is a flowchart showing a control method for the driving apparatus of the inertial sensor according to a preferred embodiment of the present invention.

As shown in FIG. 2, the driving apparatus 10 of the inertial sensor according to the preferred embodiment of the present invention is configured to include a gyro sensor 100, an analog circuit unit 110, first and second signal converting units 120 and 140, and a digital automatic gain control unit 130.

The inertial sensor 100 is a sensor including a driving mass (not shown) to detect angular velocity in three axial directions positioned in a space, a driving signal (a pulse wave) applied from the analog circuit unit 110 vibrates the driving mass (not shown), and a driving displacement signal (a sine wave) is generated by the vibration.

Here, a condition in which the driving mass (not shown) resonates due to the driving signal is that a phase difference between the driving signal and the driving displacement signal needs to be 90°. In the case in which the driving mass resonates, although the driving signal has a small amplitude, a large motion occurs at the driving mass (not shown), thereby making it possible to obtain the driving displacement signal having a large amplitude. Therefore, in order to obtain a large output from the inertial sensor, it is important to always stably perform the resonance of the driving mass.

The analog circuit unit 110 applies the driving signal to the inertial sensor 100 and receives the driving displacement signal from the inertial sensor 100 to thereby detect an amplitude value and a phase value of the driving mass resonance (S100), and includes an analog control module 111, an amplitude detection module 112 of the driving mass resonance, a phase detection module 113 of the driving mass resonance, and an analog Mux 114. A detail description thereof will be provided below.

The first signal converting unit 120 converts the amplitude value and the phase value of the driving mass resonance detected from the analog circuit unit 110 into a digital value (16 bits) (S110), where the first signal converting unit 120 may be an analog to digital (A/D) converter (see FIG. 3A).

In addition, the second signal converting unit 140 converts a control gain for the phase or amplitude of the driving mass resonance generated from the digital automatic gain control unit 130 into an analog value, where the second signal converting unit 140 may be a digital to analog (D/A) converter (see FIG. 3B).

The digital automatic gain control unit 130 generates a control gain (10 bits) for controlling the amplitude or phase of the driving mass (S130) so that the amplitude value or the phase value of the driving mass resonance converted into the digital value by the first signal converting unit 120 converges on a preset target value (S120), and transmits the control gain to the analog circuit unit 110, and the analog circuit unit 110 applies the driving signal having the control gain reflected thereto to the inertial sensor 100 (S140). A detailed description thereof will be provided below.

As described above, according to the preferred embodiment of the present invention, a size of the entire control circuit and a consumed current may be decreased and a degree of precision of the control may be increased compared to an analog scheme by controlling the phase and the amplitude of the driving mass resonance of the inertial sensor in a digital signal processing scheme using the digital automatic gain control unit 130 and the A/D converter.

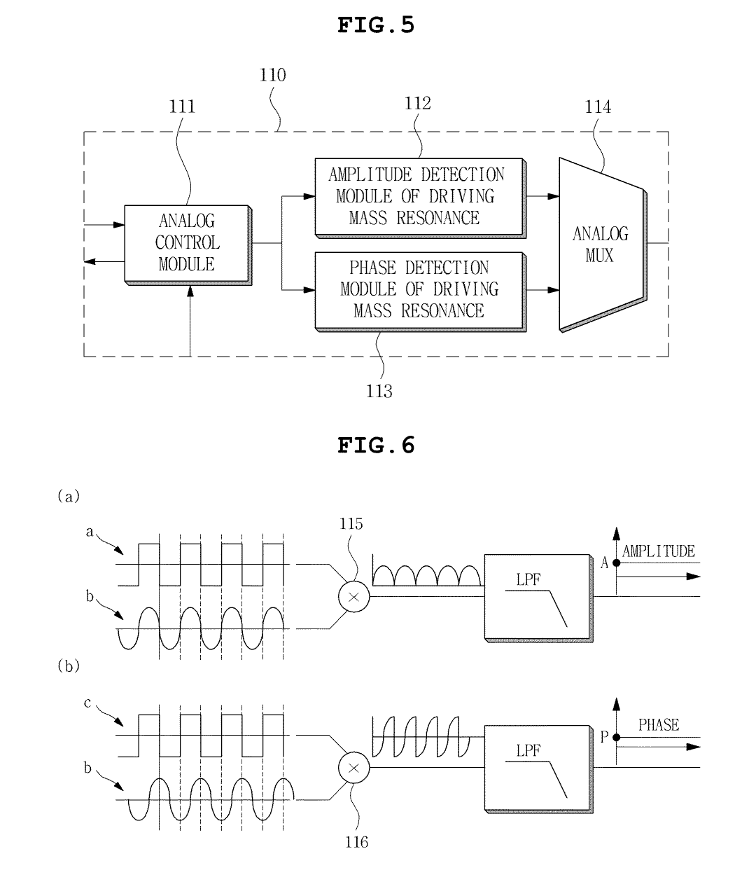

Hereinafter, a driving scheme of an analog circuit unit according to a preferred embodiment of the present invention will be described in detail with reference to FIGS. 5, 6A, and 6B.

FIG. 5 is a view showing a configuration of an analog circuit unit 110 according to a preferred embodiment of the present invention and FIGS. 6A and 6B are diagrams for describing processes detecting phase and amplitude values of driving mass resonance from the amplitude and phase detection modules 112 and 113 of the driving mass resonance according to a preferred embodiment of the present invention.

As shown in FIG. 5, the analog circuit unit 110 is configured to include an analog control module 111, the amplitude detection module 112 of the driving mass resonance, and the phase detection module 113 of the driving mass resonance, and an analog Mux 114, and detects the amplitude value and the phase value of the driving mass resonance from the driving displacement signal from the gyro sensor.

The analog control module 111 reflects the control gain for the phase or amplitude of the driving mass resonance generated from the digital automatic gain control unit 130 to a driving signal to thereby apply the driving signal to the gyro sensor 100 and receives the driving displacement signal from the inertial sensor 100.

The amplitude detection module 112 of the driving mass resonance detects the amplitude value of the driving mass resonance from the driving displacement signal received to the analog control module 111. That is, as shown in FIG. 6A, in the case in which the driving displacement signal b and a signal a having a phase retarded by 90° compared to the driving signal are multiplied by a first mixer 115 and are then filtered by a low pass filter (LPF), the amplitude value of the driving mass resonance converted into a predetermined voltage level A of a direct current (DC) form in which high frequency components are removed may be obtained. Here, the digital automatic gain control unit 130 executes an operation of the control gain for the amplitude of the driving mass resonance so that the voltage level A converges on the preset target value.

The phase detection module 113 of the driving mass resonance detects the phase value of the driving mass resonance from the driving displacement signal received to the analog control module 111. That is, as shown in FIG. 6B, in the case in which the driving displacement signal b and a driving signal c are multiplied by a second mixer 116 and are then filtered by the low pass filter (LPF), the phase value of the driving mass resonance converted into a predetermined voltage level P of the direct current (DC) form in which the high frequency components are removed may be obtained. Here, the digital automatic gain control unit 130 executes an operation of the control gain for the phase of the driving mass resonance so that the voltage level P converges on a ‘zero (0)’ value.

The analog Mux 114 selects any one of the phase value or the amplitude value of the driving mass resonance detected from the phase and amplitude detection modules 112 and 113 of the driving mass resonance and transmits the selected value to the first signal converting unit 120. That is, by a structure in which the analog Mux 114 is used for performing a digital signal processing for the phase value or the amplitude value of the driving mass resonance to thereby use one A/D converter, such that an increase in a size of the entire circuit, an increase in a consumed current, or the like which may be generated due to the A/D converter added to each of the respective detection modules may be prevented.

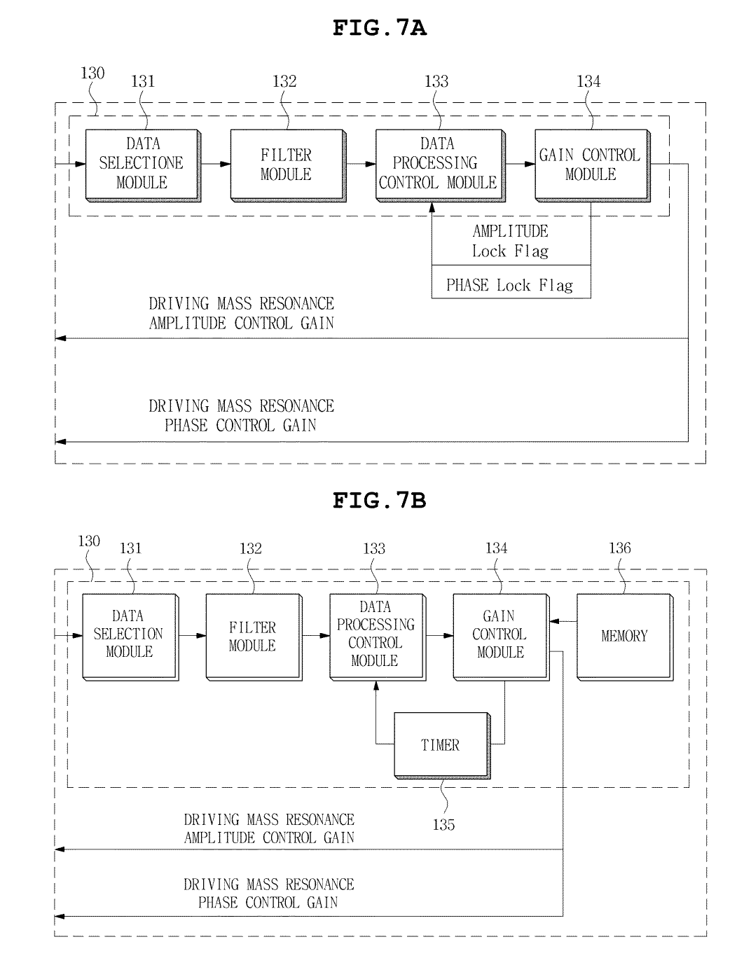

Hereinafter, a driving scheme of a digital automatic gain control unit according to a preferred embodiment of the present invention will be described in detail with reference to FIGS. 7A to 10.

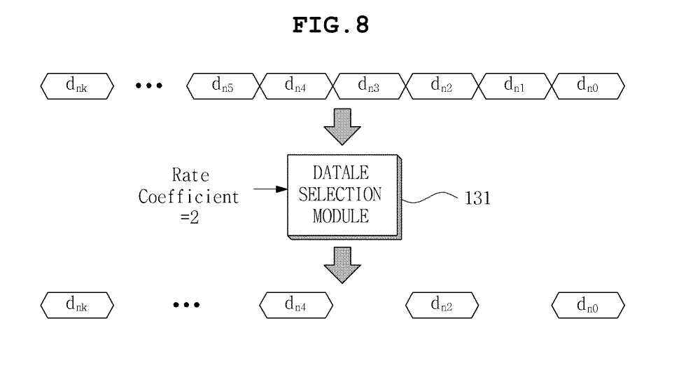

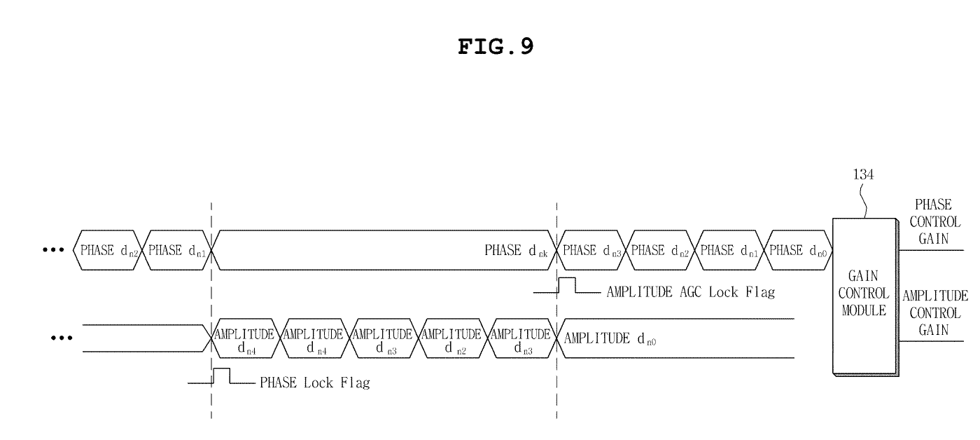

FIG. 7A is a diagram showing configuration of a digital automatic gain control unit 130 according to a preferred embodiment of the present invention, FIG. 7B is a diagram showing configuration of a digital automatic gain control unit 130 according to another preferred embodiment of the present invention, FIG. 8 is a diagram showing a procedure processing data in a data selection module 131 according to a preferred embodiment of the present invention, and FIG. 9 is a diagram showing a procedure processing data between a data processing control module 133 and a gain control module 134 according to a preferred embodiment of the present invention.

As shown in FIG. 7A, the digital automatic gain control unit 130 is configured to include the data selection module 131, a filter module 132, a data processing control module 133, and a gain control module 134, and executes an operation for generating a gain control for controlling the amplitude or phase of the driving mass resonance so that the amplitude value or the phase value of the driving mass resonance converted into the digital value by the first signal converting unit 120 converge on the preset target value.

The data selection module 131 selectively receives data for the amplitude value or the phase value of the driving mass resonance depending on a preset rate coefficient by considering a response speed of the driving mass when the control gain for the amplitude or phase of the driving mass resonance generated from the digital automatic gain control unit 130 is applied to the driving mass.

That is, as shown in FIG. 8, the data selection module 131 selectively receives only data corresponding to multiples of two such as dₙ₂, dₙ₄g, dₙ₆ to dₙₖ among data (dₙ₁ to dₙₖ) for the amplitude value or the phase value of the driving mass resonance through the first signal converting unit 120 from the analog circuit unit 110, in the case in which the rate coefficient is set to 2.

Thereby, another control gain again generated from a process in which the control gain for the phase or amplitude generated from the digital automatic gain control unit 130 is reflected to the driving mass, is applied to the driving mass, such that oscillation of the entire system or physical damage to the driving mass due to an abnormal motion of the driving mass which is likely to generate may be prevented. Here, the rate coefficient may be determined depending on physical property of the driving mass of the inertial sensor.

The filter module 132 filters out a noise include in the phase value or the amplitude value of the driving mass resonance selected by the data selection module 131, and may be a digital low pass filter in this specification. That is, the phase value or the amplitude value transmitted from the first signal converting unit 120 is applied in the DC form, but the filter module 132 removes the noise generated during an information processing.

The gain control module 134 compares and determines whether or not the phase value or the amplitude value of the driving mass resonance filtered by the filter module 132 has converged on the preset target value, and executes the operation of the control gain for the phase or amplitude of the driving mass resonance to reach the target value when the phase value or the amplitude value has not converged on the target value.

That is, in a case of the phase of the driving mass resonance, as shown in FIG. 6, the operation of the control gain for the phase is executed until the phase difference between the driving signal c and the driving displacement signal b may be maintained at 90°, and in a case of the amplitude of the driving mass resonance, the operation of the control gain for the amplitude is executed so that the amplitude value converges on a predetermined magnitude enabling the driving mass to always resonate at a constant amplitude. Here, the gain control module 134 may be a proportional integral control (PID control).

In addition, after any one of the amplitude or phase is converged on the preset target value by the gain control module 134, the data processing control module 133 executes an operation of the control gain so that the other is converged on the preset target value.

That is, as shown in FIG. 9, in a case of a state in which the gain control module 134 operates the control gain for the phase control of the driving mass resonance, the operation for the control gain of the phase control is executed until the phase converges on the preset target value in a state in which the operation for generating the control gain for the amplitude control is held, and in the case in which the phase converges on the target value, a phase lock flag signal indicating that the phase value is maintained is transmitted to the data processing module.

Further, the data processing control module 133 receiving the phase lock flag signal no longer transmits the data for the phase value of the driving mass resonance to the gain control module 134 and transmits only data for the amplitude value to the gain control module, and the gain control module 134 executes the operation for the control gain of the amplitude control until the amplitude of the driving mass resonance converges on the preset target value and transmits an amplitude lock flag signal indicating that the amplitude value is maintained to the data processing module in the case in which the amplitude converges on the target value to thereby sequentially execute the operations with respect to the control gain of the phase and the amplitude of the driving mass resonance.

As shown in FIG. 7B, the digital automatic gain control unit 130 may be configured to include the data selection module 131, the filter module 132, the data processing control module 133, and the gain control module 134, as well as a memory 136 and a timer 135.

The memory 136 stores the pre-operated control gain for the amplitude or phase of the driving mass resonance so that the amplitude value or the phase value of the driving mass resonance may approach the target value, and the gain control module 134 may use the control gain stored in the memory 136 at the time of initially driving the driving mass as a control gain for controlling the phase or amplitude of the driving mass resonance.

The timer 135 counts a time for which the operation of the control gain for the amplitude or phase of the driving mass resonance are executed in the gain control module 134, determines whether or not the operation execution time exceeds a preset time value, and then transmits a timeout signal to the data processing control module 133 and the gain control module 134 when the operation execution time exceeds the preset time value.

That is, the data processing control module 133 transmits only data for other signals to the gain control module 134 after receiving the timeout signal, the gain control module 134 executes an operation of a control gain for other signals after terminating the operation execution, and the timer initializes the counted time value when receiving the lock flag signal for the amplitude or phase of the driving mass resonance from the gain control module 134 or transmitting the timeout signal.

According to the preferred embodiment of the present invention, the size of the entire control circuit and the consumed current may be decreased and the degree of precision of the control may be increased compared to the analog scheme by controlling the phase and the amplitude of the driving mass resonance for the inertial sensor in the digital signal processing scheme using the digital automatic gain control unit and the A/D converter.

In addition, the data selection module considers the response speed of the driving mass for the control gain in the phase or amplitude of the driving mass resonance generated from the gain control module to selectively receive the data for the phase value or amplitude value of the driving mass resonance, such that the damage to the driving mass or the oscillation phenomenon of the entire system due to the application of the new control gain before the driving mass resonance becomes stable by the previously reflected control gain may be prevented.

In addition, the data processing module controls so that the operations of the control gain for the amplitude or phase of the driving mass resonance are each divided and are sequentially executed in the gain control module, such that the damage to the driving mass due to the abnormal operation of the driving mass which may be generated due to the simultaneous adjustment of the phase and the amplitude of the driving mass resonance may be prevented, thereby making it possible to secure stability and precision of the entire control circuit.

In addition, the timer and the memory counts the time of the operation execution of the control gain for the phase or amplitude of the driving mass resonance in the gain control module to terminate the operation execution by the timeout signal when the time of the operation execution exceeds a predetermined time and to then execute the operation of the control gain for other signals, such that the phase or amplitude of the driving mass resonance may be efficiently controlled, thereby making it possible to secure stability of the control of the driving mass resonance by the driving circuit.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An apparatus for driving an inertial sensor, the apparatus comprising:
an inertial sensor including at least one driving mass;
an analog circuit unit detecting an amplitude value and a phase value of a driving mass resonance from a driving displacement signal of the inertial sensor;
a first signal converting unit converting the amplitude value and the phase value into a digital value;
a digital automatic gain control unit selectively executing an operation of a control gain for an amplitude or phase of the driving mass resonance so that any one of the amplitude value or the phase value received from the first signal converting unit first converges on a preset target value; and
a second signal converting unit converting the control gain into an analog value and transmitting the analog value to the analog circuit unit.

2. The apparatus for driving the inertial sensor as set forth in claim 1, wherein the digital automatic gain control unit selectively receives data for a signal of any one of the amplitude value or the phase value from the first signal converting unit depending on a response speed of the driving mass applied with the control gain of the amplitude or phase.

3. The apparatus for driving the inertial sensor as set forth in claim 1, wherein the first signal converting unit is an analog to digital (A/D) converter.

4. The apparatus for driving the inertial sensor as set forth in claim 1, wherein the second signal converting unit is a digital to analog (D/A) converter.

5. The apparatus for driving the inertial sensor as set forth in claim 1, wherein the analog circuit unit includes:
an analog control module generating a driving signal to which the control gain for the phase or amplitude of the driving mass resonance is reflected, applying the driving signal to the inertial sensor, and receiving a driving displacement signal from the inertial sensor;
an amplitude detection module of the driving mass resonance mixing the driving displacement signal with a signal having a phase retarded by 90° compared to the driving signal to thereby detect the amplitude value of the driving mass resonance;
a phase detection module of the driving mass resonance mixing the driving displacement signal with the driving signal to thereby detect the phase value of the driving mass resonance; and
an analog Mux selectively transmitting the amplitude value or the phase value of the driving mass resonance to the digital automatic gain control unit.

6. The apparatus for driving the inertial sensor as set forth in claim 1, wherein the digital automatic gain control unit includes:
a data selection module selectively receiving data for the amplitude value or the phase value of the driving mass resonance depending on a preset rate coefficient by considering a response speed of the driving mass applied with the control gain;
a gain control module executing an operation for generating the control gain of the phase of amplitude so that the amplitude or phase of the driving mass resonance reaches a preset target value; and
a data processing control module performing a control so that an operation of a control gain for other signal is executed, after any one of the amplitude or phase of the driving mass resonance converges on the preset target value by the gain control module.

7. The apparatus for driving the inertial sensor as set forth in claim 6, wherein the digital automatic gain control unit includes:
a memory storing a pre-operated control gain for the amplitude or phase of the driving mass resonance so that the amplitude value or the phase value of the driving mass resonance approaches the target value; and
a timer counting an operation execution time of the control gain for the amplitude or phase of the driving mass resonance in the gain control module.

8. The apparatus for driving the inertial sensor as set forth in claim 7, wherein the gain control module uses the control gain stored in the memory at the time of initially driving the driving mass as a control gain for controlling the phase or amplitude of the driving mass resonance.

9. The apparatus for driving the inertial sensor as set forth in claim 7, wherein the timer determines whether or not the operation execution time exceeds a preset time value, and then transmits a timeout signal to the data processing control module and the gain control module when the operation execution time exceeds the preset time value.

10. The apparatus for driving the inertial sensor as set forth in claim 9, wherein the data processing control module transmits only data for other signal to the gain control module after receiving the timeout signal, and
the gain control module executes an operation of a gain control for other signals after terminating the operation execution.

11. The apparatus for driving the inertial sensor as set forth in claim 9, wherein the timer initializes the counted time value when receiving a lock flag signal for the amplitude or phase of the driving mass resonance from the gain control module or transmitting the timeout signal.

12. The apparatus for driving the inertial sensor as set forth in claim 7, wherein the digital automatic gain control unit further includes a filter unit provided between the data selection module and the gain control module and removing a noise included in the amplitude value or the phase value of the driving mass resonance.

13. The apparatus for driving the inertial sensor as set forth in claim 6, wherein the gain control module transmits a lock flag signal indicating that a value converged on the preset target value is maintained to the data processing control module, when any one of the phase or amplitude of the driving mass resonance converges on the preset target value.

14. The apparatus for driving the inertial sensor as set forth in claim 13, wherein the data processing control module transmits only data for a signal not converging on the preset target value among the phase or amplitude of the driving mass resonance when receiving the lock flag signal from the gain control module.

15. A controlling method of an apparatus for driving an inertial sensor, the method comprising:
detecting, by an analog circuit unit, an amplitude value and a phase value of a driving mass resonance from a driving displacement signal of an inertial sensor;
converting, by a first signal converting unit, the amplitude value or the phase value into a digital value;
selectively executing, by a digital automatic gain control unit, an operation of a control gain for an amplitude or phase of the driving mass resonance so that any one of the amplitude value or the phase value received from the first signal converting unit first converges on a preset target value; and
converting, by a second signal converting unit, the control gain into an analog value to thereby transmit the analog value to the analog circuit unit.

16. The controlling method as set forth in claim 15, wherein the selectively executing, by a digital automatic gain control unit, of the operation of the control gain for the amplitude or phase of the driving mass resonance includes:
selectively receiving data for a signal of any one of the amplitude value or the phase value from the first signal converting unit depending on a response speed of the driving mass applied with the control gain of the amplitude or phase; and
executing an operation of a control gain for other signal after any one of the amplitude value or the phase value converges on a preset target value by the operation of the control gain for the amplitude or phase of the driving mass resonance.

17. The controlling method as set forth in claim 15, wherein the detecting of the amplitude value and the phase value of the driving mass resonance includes:
applying, by an analog control module, a driving signal having the control gain reflected thereto to the inertial sensor and receiving a driving displacement signal from the inertial sensor;
mixing, by an amplitude detection unit of the driving mass resonance, the driving displacement signal with a signal having a phase retarded by 90° compared to the driving signal to thereby detect the amplitude value of the driving mass resonance;
mixing, by a phase detection unit of the driving mass resonance, the driving displacement signal with the driving signal to thereby detect the phase value of the driving mass resonance; and
selectively transmitting, by an analog Mux, the amplitude value or the phase value of the driving mass resonance to the digital automatic gain control unit.

18. The controlling method as set forth in claim 15, wherein the selectively executing of the operation of the control gain for the amplitude or phase of the driving mass resonance includes:
selectively receiving, by a data selection module, data for the amplitude value or the phase value depending on a preset rate coefficient;
comparing, by a gain control module, the amplitude value or the phase value with a preset target value and generating a control gain for the phase or amplitude when the comparison result is different; and
performing, by a data processing control module, a control so that an operation of a control gain for other signal is executed, after any one of the amplitude or phase of the driving mass resonance converges on the preset target value by the gain control module.

19. The controlling method as set forth in claim 18, further comprising, after the generating of the control gain by the gain control module,
counting, by a timer, an operation execution time of the control gain for the amplitude or phase of the driving mass resonance by the gain control module and determining whether or not the operation execution time exceeds a preset time value; and
transmitting, by the timer, a timeout signal to the data processing control module and the gain control module when the operation execution time exceeds the preset time value.

20. The controlling method as set forth in claim 19, further comprising:
transmitting, by the data processing control module, only data for other signal to the gain control module after receiving the timeout signal, and
executing, by the gain control module, an operation of a gain control for other signal after terminating the operation execution.

21. The controlling method as set forth in claim 19, further comprising, after the selectively receiving, by the data selection module, of the data for the amplitude value or the phase value, removing, by a filter unit, a noise included in the amplitude value or the phase value.

22. The controlling method as set forth in claim 18, wherein the performing, by the data processing control module, of the control so that the operation of the control gain for other signals is executed includes:
transmitting, by the gain control module, a lock flag signal when any one of the phase or amplitude of the driving mass resonance converges on the preset target value to the data processing control module; and
transmitting, by the data processing control module receiving the lock flag signal, only data for a signal not converging on the preset target value among the phase or amplitude to the gain control module.

23. The controlling method as set forth in claim 15, wherein the first signal converting unit is an analog to digital (A/D) converter.

24. The controlling method as set forth in claim 15, wherein the second signal converting unit is a digital to analog (D/A) converter.
